(19) United States
(12) Patent Application Publication
(10) Pub. No.: US 2026/0341338 A1
(43) Pub. Date: Oct. 29, 2026

(54) MEMORY DEVICE HAVING MEMORY STRUCTURE INCLUDING PROCESSING ELEMENTS

(71) Applicant: Samsung Electronics Co., Ltd., Suwon-si (KR)

(72) Inventor: Jeonil Lee, Suwon-si (KR)

(73) Assignee: Samsung Electronics Co., Ltd., Suwon-si (KR)

(21) Appl. No.: 19/657,550

(22) Filed: Apr. 24, 2026

(30) Foreign Application Priority Data
Apr. 25, 2025 (KR) 10-2025-0054649

(51) Int. Cl. G11C 11/4091; G11C 11/4093

(52) U.S. Cl. CPC G11C 11/4091; G11C 11/4093

(57) ABSTRACT

A memory device having a memory structure that efficiently feeds a processing element is disclosed. The memory device includes a first stack structure and a second stack structure disposed on the first stack structure. The first stack structure includes a memory cell array in which a plurality of sub-cell blocks are divided into a first sub-cell block group and a second sub-cell block group. The second stack structure includes first sense amplifiers connected to sub-cell blocks belonging to the first sub-cell block group, second sense amplifiers connected to sub-cell blocks belonging to the second sub-cell block group, a multiplexer circuit corresponding to each of the first sub-cell block group and the second sub-cell block group, and a processing element. The processing element includes a processing unit that performs a logical operation on data transmitted by the multiplexer circuit as an operand.

### CROSS-REFERENCE TO RELATED APPLICATIONS

This present application claims priority to and the benefit under 35 U.S.C. § 119(a)-(d) of Korean Patent Application No. 10-2025-0054649, filed on Apr. 25, 2025, in the Korean Intellectual Property Office, the entire disclosure of which is incorporated herein by reference.

### FIELD

The disclosed concepts relate to memory devices, and more particularly, to memory devices having a memory structure that is efficiently fed to a processing element.

### BACKGROUND

Artificial intelligence (AI) is intelligence implemented by machines, which represents the ability of computer programs or machines to think and learn. A machine may be trained for each task by performing AI calculations by using one or more computers. AI computations may include computations represented by one or more machine learning models. Neural networks belong to a sub-field of machine learning models. A neural network may be configured to perform a number of operations, such as vector or matrix operations, to produce classifications, predictions, or segmentations with respect to inputs. Data to be used to perform computational operations may be collected by, for example, an image sensor (including a camera or recorder) and stored in memory devices.

To process the data more efficiently at high throughput, processing elements that perform the computational operations may be added to the memory devices. Simply adding the processing elements to meet the computational demands incurs significant and unacceptable area overhead within the dynamic random-access memory (DRAM) die.

### SUMMARY

The disclosed concepts provide memory devices having a memory structure that efficiently feeds processing elements that perform matrix-matrix multiplication, matrix-vector multiplication, and/or bit vector operations associated with data compression while reducing area overhead of a dynamic random-access memory (DRAM) die.

According to aspects of the present disclosed concepts, there is provided a memory device including a first stack structure and a second stack structure disposed on the first stack structure. The first stack structure may include a memory cell array region including a bank divided into a plurality of sub-cell blocks, wherein the plurality of sub-cell blocks are included in a first sub-cell block group and a second sub-cell block group, and each of the first sub-cell block group and the second sub-cell block group includes at least two or more sub-cell blocks. The second stack structure includes a sense amplifier region including sense amplifiers connected to memory cells through a plurality of bit lines of the plurality of sub-cell blocks, the sense amplifiers including first sense amplifiers connected to sub-cell blocks belonging to the first sub-cell block group and second sense amplifiers connected to sub-cell blocks belonging to the second sub-cell block group, a multiplexer circuit region including a multiplexer circuit corresponding to each of the first sub-cell block group and the second sub-cell block group, and a processing element area including a processing element corresponding to each of the first sub-cell block group and the second sub-cell block group, wherein the processing element includes a processing unit that performs a logical operation on data transmitted by the multiplexer circuit as an operand.

According to aspects of the present disclosed concepts, there is provided a memory device including a first stack structure, a second stack structure disposed on the first stack structure, and a third stack structure disposed on the second stack structure. The first stack structure may include a memory cell array region including a bank divided into a plurality of sub-cell blocks, the plurality of sub-cell blocks being included in a first sub-cell block group and a second sub-cell block group, each of the first sub-cell block group and the second sub-cell block group including at least two sub-cell blocks. The second stack structure may include a sense amplifier region including sense amplifiers connected to memory cells through a plurality of bit lines of the plurality of sub-cell blocks, the sense amplifiers including first sense amplifiers connected to sub-cell blocks belonging to the first sub-cell block group and second sense amplifiers connected to sub-cell blocks belonging to the second sub-cell block group, and a multiplexer circuit region including a multiplexer circuit corresponding to each of the first sub-cell block group and the second sub-cell block group. The third stack structure may include a processing element region including processing elements corresponding to each of the first sub-cell block group and the second sub-cell block group, the processing elements including a processing unit that performs a logical operation on data transmitted by the multiplexer circuit as an operand.

According to aspects of the present disclosed concepts, there is provided a memory device including a memory cell array including a bank divided into a plurality of sub-cell blocks, wherein the plurality of sub-cell blocks may be included in a first sub-cell block group and a second sub-cell block group, and each of the first sub-cell block group and the second sub-cell block group may include at least two sub-cell blocks, sense amplifiers connected to memory cells through a plurality of bit lines of the plurality of sub-cell blocks, wherein the sense amplifiers may include first sense amplifiers connected to sub-cell blocks belonging to the first sub-cell block group and second sense amplifiers connected to sub-cell blocks belonging to the second sub-cell block group, a multiplexer circuit corresponding to each of the first sub-cell block group and the second sub-cell block group, a processing element corresponding to each of the first sub-cell block group and the second sub-cell block group, wherein the processing element may include a processing unit that performs a logical operation on data transmitted by the multiplexer circuit as an operand, a first switch circuit connecting the first sense amplifiers and the processing element by the multiplexer circuit, and a second switch circuit connecting the second sense amplifiers and the processing element by the multiplexer circuit.

### BRIEF DESCRIPTION OF THE DRAWINGS

Embodiments will be more clearly understood from the following detailed description taken in conjunction with the accompanying drawings in which:

FIG. 1 is a diagram illustrating a system including a memory device performing internal processing operations according to some embodiments;

FIG. 2 is a block diagram illustrating a configuration of a memory device according to some embodiments;

FIGS. 3 to 6 are diagrams illustrating a semiconductor structure of the memory device of FIG. 2;

FIGS. 7 to 9 are diagrams illustrating processing elements within a memory device according to some embodiments;

FIGS. 10 to 13 are diagrams illustrating banks within a memory device according to some embodiments; and

FIG. 14 is a block diagram of a system for illustrating an electronic device including a memory device according to some embodiments.

### DETAILED DESCRIPTION

The memory devices described in the present embodiments may include process-in-memory (PIM) structures that enable computational capabilities. The potential for accelerating neural network computation or calculations has been demonstrated due to the large internal bandwidth of PIM, reduction in data movement, and massive memory parallelism. Deep neural networks (DNN) are considered as a promising approach for realizing artificial intelligence, and their effectiveness has been proven in a number of applications. DNN training requires both high accuracy and wide dynamic range, which requires efficient floating-point operations. Tensor computation, which includes the majority of floating-point operations and takes up the largest amount of time in DNN training, is a key and core operation for acceleration. Tensor computation plays an important role in a wide range of applications in deep learning.

Techniques that perform general matrix-matrix multiplication (GEMM) or generalized matrix vector multiplication (GEMV) in deep learning and floating point multiplications for tensor computation may perform concurrent lookup operations in a DRAM-based lookup table (LUT). GEMM or GEMV technology may establish matrix multiplication and convolution operations of arbitrary size as vector operations. In order to perform matrix-matrix or matrix-vector calculations, a loop tiling technique, also called loop nest optimization, which divides the iteration space of the loop into smaller chunks or blocks, may be applied. Accordingly, smaller chunks or blocks may be calculated in parallel when processing input data.

LUT entries and input data for loop tiling may be expressed as input matrices and received row by row. In order to provide higher internal bandwidth and higher computational performance, input data may be configured to be efficiently stored and accessed within the DRAM and fed (also referred to as supplied or provided) to processing element(s). Hereinafter, a memory structure that efficiently feeds processing element(s) within the DRAM is described.

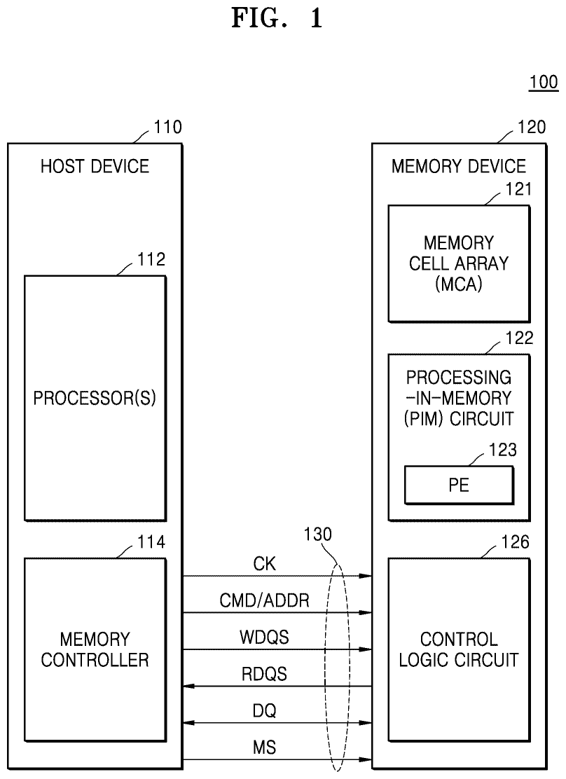

FIG. 1 is a diagram illustrating a system 100 including a memory device that performs internal processing operations according to some embodiments.

Referring to FIG. 1, the system 100 may be configured to execute applications such as high-performance computing, graphics operations, and the like, or applications such as learning systems such as DNNs. These applications require a lot of computational and memory capabilities to execute jobs or tasks in parallel, train other data sets, and learn with high accuracy, and emphasize power efficiency and low latency.

The system 100 may include a host device 110 and a memory device 120. The host device 110 may be used to solve an overall task or operation using a parallel processing approach in which the overall task or operation is divided into smaller tasks that are executed in parallel on a number of computing entities (e.g., processors 112, cores within the processors 112, and processing-in-memory (PIM) circuits 122. A task includes a number of tasks that are organized in a hierarchical structure, and the tasks may refer to executable code to be executed by a computing entity, data to be processed, data to be retrieved from a memory device 120 by the computing entity, manipulated through execution of the code, and then stored.

The host device 110 may be communicatively connected to the memory device 120 via a bus 130. The host device 110 may be, for example, a computing system such as a computer, a laptop, a server, a workstation, a portable communication terminal, a personal digital assistant (PDA), a portable multimedia player (PMP), a smartphone, or a wearable device. Alternatively, the host device 110 may be a part of components included in the computing system such as a graphics card.

The host device 110 may include one or more processor(s) 112 that perform general computer operations within the system 100 and a memory controller 114 that manages data transmission and reception to/from the memory device 120. The processor(s) 112 is a primary component of the system 100 that processes and manages commands and is mainly responsible for executing the operating system and applications. In addition, the processor(s) 112 may be distributed across multiple computing entities to allow the workload to be processed in parallel to solve complex tasks or operations. The processor(s) 112 may include processing units such as a neural processing unit (NPU), a central processing unit (CPU), a digital signal processor (DSP), a graphics processing unit (GPU), a cryptographic processing unit, a physical processing unit, a machine learning processing unit, etc.

The processor(s) 112 may improve efficiency by distributing execution of various computational tasks, instructions, or kernels to other processors or offloading them to the memory device 120. A kernel is defined as one or more instructions that are grouped together to execute a task or a definable sub-task. The PIM circuit 122 of the memory device 120 may perform computational processing by the kernel offloaded by the processor(s) 112. Various types of computational processing operations may be performed in the PIM circuit 122, and as an example, at least some of the neural network operations (e.g., GEMM, GEMV, and/or tensor calculations) related to artificial intelligence may be performed in the PIM circuit 122. For example, the processor(s) 112 may control the memory device 120 through the memory controller 114 so that at least some of the neural network operations are performed by the PIM circuit 122.

The memory controller 114 may access the memory device 120 according to a memory request of the host device 110. The memory controller 114 may control a write operation or a read operation for the memory device 120 by providing a command CMD and an address ADDR to the memory device 120. In addition, data DQ for a write operation and read data DQ may be transmitted and received between the memory controller 114 and the memory device 120. The memory access operations may be performed through the bus 130 between the memory controller 114 and the memory device 120.

The bus 130 may be composed of clock signal lines transmitting a main clock signal CK, a write data strobe signal WDQS and a read data strobe signal RDQS, command/address signal lines transmitting a command/address CMD/ADDR, and data lines transmitting data DQ.

The bus 130 may operate in a PIM specification and/or in an HBM specification under the control by the host device 110 (e.g., the memory controller 114). For brevity of the drawing, the clock signal lines, command/address signal lines, and data lines between the memory controller 114 and the memory device 120 are illustrated as being connected as one signal line each, but in reality, they may be connected through multiple signal lines. The bus 130 may be implemented as one channel or multiple channels including multiple signal lines. The bus 130 may be referred to as a channel, and in the following embodiments, the terms “bus 130” and “channel” may be used interchangeably.

The memory device 120 may write data or read data under the control by the memory controller 114. For example, the memory device 120 may be a double data rate synchronous dynamic random-access memory (DDR SDRAM) device. However, the scope of the present inventive concept is not limited thereto, and the memory device 120 may be any one of volatile memory devices such as low power double data rate (LPDDR) SDRAM, Wide I/O DRAM, high bandwidth memory (HBM), hybrid memory cube (HMC), etc. According to embodiments, the memory device 120 may be any one of nonvolatile memory devices such as flash memory, phase-change RAM (PRAM), magnetic RAM (MRAM), resistive RAM (SRAM), ferroelectric RAM (FRAM), etc.

The memory device 120 may operate in one of the operation modes of the memory mode and the internal processing mode. The memory mode refers to an operation mode in which a general data transaction operation is performed under the control by the memory controller 114, and the internal processing mode refers to an operation mode in which an internal processing operation is performed under the control by the memory controller 114. In the data transaction operation, the memory device 120 may perform a command and address reception operation and a data exchange operation according to memory mode timing parameters defined in the DDR, LPDDR, and/or HBM protocols under the control by the memory controller 114. In the internal processing operation, the memory device 120 may perform a command and address reception operation and a data exchange operation according to the internal processing mode timing parameters defined in the PIM protocol under the control by the memory controller 114. The memory mode timing parameters and the internal processing mode timing parameters may be set differently from each other. Depending on embodiments, the internal processing mode timing parameters may be set to values that are relatively smaller than the memory mode timing parameters.

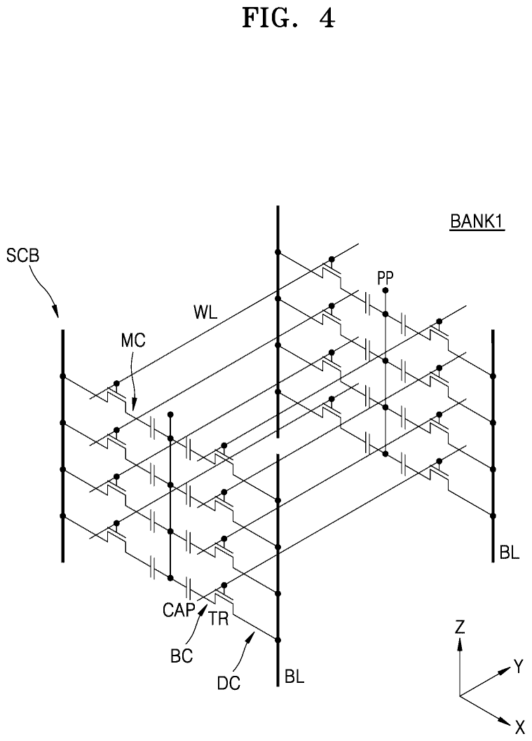

The memory device 120 may include a memory cell array (MCA) 121, a PIM circuit 122, and a control logic circuit 126. The MCA 121 may be organized into banks and may include a plurality of word lines, a plurality of bit lines, and a plurality of memory cells formed at points where the word lines intersect with the bit lines. Each of the plurality of memory cells may include a DRAM cell (MC, FIG. 4) consisting of one cell transistor TR and one cell capacitor CAP connected to the cell transistor TR.

The PIM circuit 122 may be equipped with one or more processing elements 123 configured to execute a kernel offloaded by the host device 110. The host device 110 (e.g., the memory controller 114) may start an internal processing operation of the PIM circuit 122 by issuing a PIM command through the bus 130. The PIM circuit 122 is hardware having a processing function, similar to the processor(s) 112 included in the host device 110. When referring to the PIM circuit 122 as an internal processor, the term “internal” means existing within the memory device 120. Therefore, a processor existing “outside” the memory device 120 may refer to, for example, the processor(s) 112 of the host device 110.

The control logic circuit 126 may control overall operations of the memory device 120. The control logic circuit 126 may generate control signals to perform a write operation, a read operation, a refresh operation, and/or an internal processing operation of the memory device 120 based on a command CMD received from the memory controller 114.

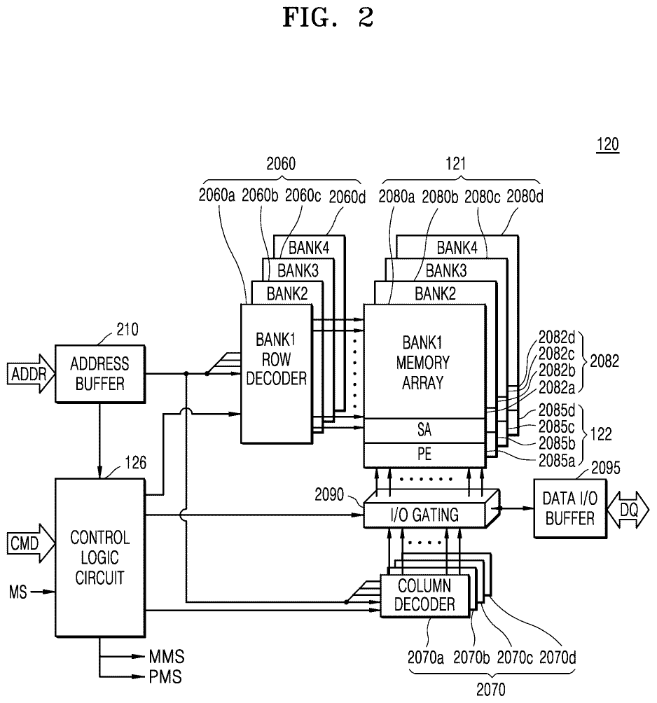

FIG. 2 is a block diagram showing the configuration of the memory device 120 according to some embodiments. FIG. 2 shows the configuration of the memory device 120 of FIG. 1. Hereinafter, the suffixes attached to reference numbers (e.g., a in 2080a, b in 2080b, c in 2080c, d in 2080d) are intended to distinguish multiple circuits that perform the same function.

Referring to FIG. 2, the memory device 120 may include an address buffer 210, a control logic circuit 126, a row decoder 2060, a column decoder 2070, an MCA 121, a sense amplifier 2082, a PIM circuit 122, an input/output gating circuit 2090, and a data input/output buffer 2095. Although not shown in FIG. 2, the memory device 120 may further include a clock buffer, a refresh control circuit, a voltage generation circuit, a bank control logic, etc.

The MCA 121 may include first to fourth bank arrays 2080a, 2080b, 2080c, and 2080d. Each of the first to fourth bank arrays 2080a, 2080b, 2080c, and 2080d may include a plurality of word lines, a plurality of bit lines, and a plurality of memory cells formed at points where the word lines intersect with the bit lines.

The row decoder 2060 may include first to fourth bank row decoders 2060a, 2060b, 2060c, and 2060d connected to the first to fourth bank arrays 2080a, 2080b, 2080c, and 2080d, respectively, and the column decoder 2070 may include first to fourth bank column decoders 2070a, 2070b, 2070c, and 2070d connected to the first to fourth bank arrays 2080a, 2080b, 2080c, and 2080d, respectively. The sense amplifier 2082 may include first to fourth sense amplifiers 2082a, 2082b, 2082c, and 2082d connected to the first to fourth bank arrays 2080a, 2080b, 2080c, and 2080d, respectively, and the PIM circuit 122 may include first to fourth processing elements 2085a, 2085b, 2085c, and 2085d connected to the first to fourth bank arrays 2080a, 2080b, 2080c, and 2080d, respectively.

The first to fourth bank arrays 2080a, 2080b, 2080c, and 2080d, the first to fourth bank row decoders 2060a, 2060b, 2060c, and 2060d, the first to fourth bank column decoders 2070a, 2070b, 2070c, and 2070d, the first to fourth sense amplifiers 2082a, 2082b, 2082c, and 2082d, and the first to fourth processing elements 2085a, 2085b, 2085c, and 2085d may respectively configure the first to fourth banks. The first to fourth bank row decoders 2060a, 2060b, 2060c, and 2060d, the first to fourth bank column decoders 2070a, 2070b, 2070c, and 2070d, the first to fourth sense amplifiers 2082a, 2082b, 2082c, and 2082d, and the first to fourth processing elements 2085a, 2085b, 2085c, and 2085d may be referred to as core circuits of the first to fourth banks BANK1 to BANK4. Although the present embodiments illustrates an example of the memory device 120 including four banks, the memory device 120 may include a different number of banks depending on embodiments.

The address buffer 210 may receive an address ADDR including a row address and a column address from the memory controller 114. In addition, the address buffer 210 may receive a bank address and provide the bank address to the bank control logic, provide the received row address to the row decoder 2060, and provide a received column address to the column decoder 2070. The bank control logic may generate bank control signals in response to the bank address. In response to the bank control signals, a bank row decoder corresponding to the bank address among the first to fourth bank row decoders 2060a, 2060b, 2060c, and 2060d may be activated, and a bank column decoder corresponding to the bank address among the first to fourth bank column decoders 2070a, 2070b, 2070c, and 2070d may be activated.

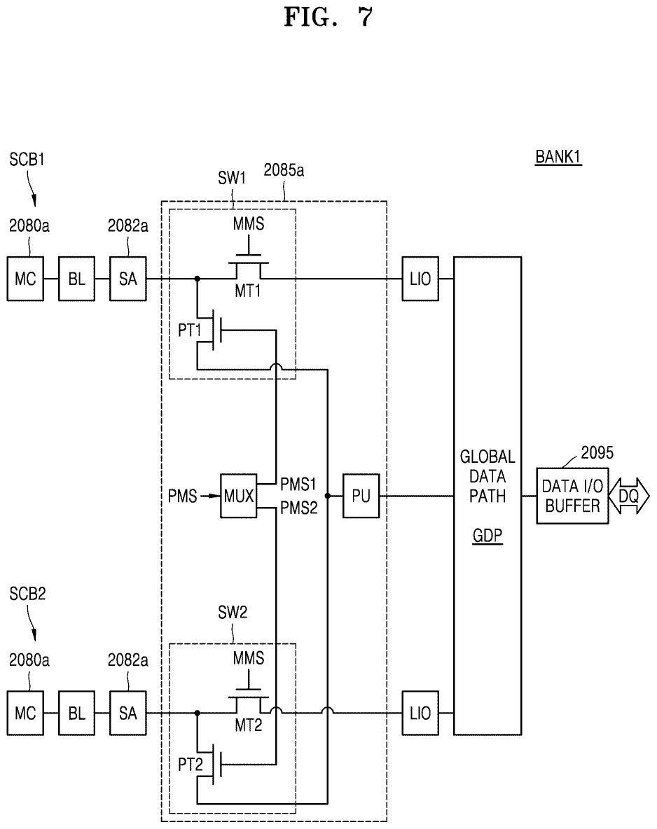

The control logic circuit 126 may control overall operations of the memory device 120. The control logic circuit 126 may generate control signals to perform a write operation, a read operation, a refresh operation, and/or an internal processing operation of the memory device 120. The control logic circuit 126 may include a mode register for setting multiple operation options of the memory device 120 and a command decoder for decoding a command CMD received from the memory controller 114. The control logic circuit 126 may generate a memory mode signal MMS or a processing mode signal PMS based on a mode selection signal MS received from the memory controller 114. The memory mode signal MMS and the processing mode signal PMS will be described with reference to FIG. 7.

The input/output gating circuit 2090 may include circuits for gating input/output data DQ, a column selection circuit, an input data mask logic, read data latches for storing read data output from the first to fourth bank arrays 2080a, 2080b, 2080c, and 2080d, and a write driver for writing data to the first to fourth bank arrays 2080a, 2080b, 2080c, and 2080d. Read data output from one of the first to fourth bank arrays 2080a, 2080b, 2080c, and 2080d may be detected by the sense amplifier 2082 corresponding to one bank array and stored in read data latches. The write data to be written to the memory cell array of one of the first to fourth bank arrays 2080a, 2080b, 2080c, and 2080d may be provided from the memory controller 114 to the data input/output buffer 2095. The data provided to the data input/output buffer 2095 may be written to one bank array through the write driver. The address buffer 210, the control logic circuit 126, the input/output gating circuit 2090, and the data input/output buffer 2095 may be referred to as peripheral circuits of the memory device 120.

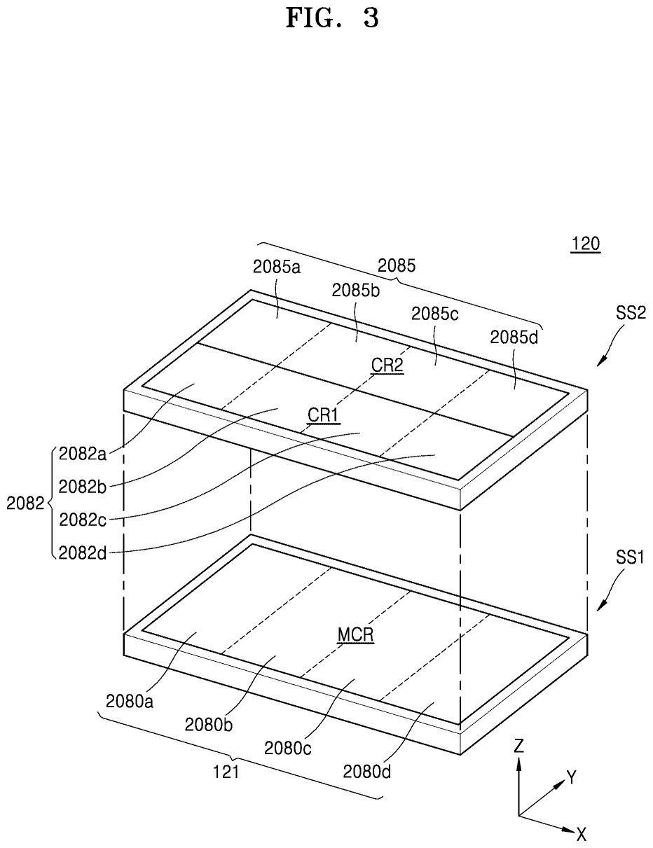

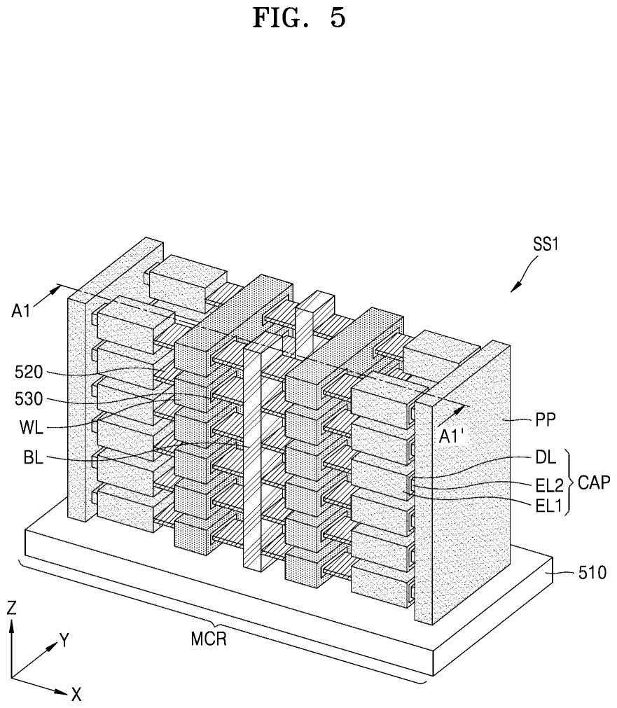

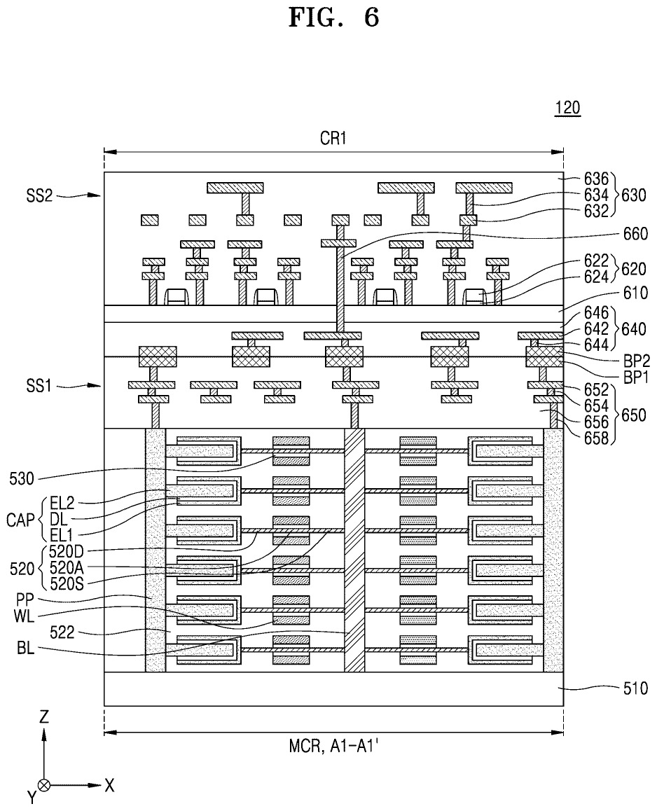

FIGS. 3 to 6 are diagrams for explaining the semiconductor structure of the memory device of FIG. 2. FIG. 4 is a circuit diagram showing a first bank BANK1 within the MCA 121, FIG. 5 is a perspective view showing a sub-cell block SCB within the first bank BANK1, and FIG. 6 is a cross-sectional view of a memory device taken along line A1-A1′ of FIG. 5. The semiconductor structure of the first bank BANK1 described with reference to FIGS. 4 and 5 may be applied equally to the second to fourth banks BANK2 to BANK4. Because the first to fourth banks BANK1 to BANK4 have the same semiconductor structure, the first bank BANK1 may be used interchangeably as a bank.

Referring to FIG. 3, the memory device 120 may have a structure in which the first stack structure SS1 and the second stack structure SS2 are stacked in a vertical direction. For example, the first stack structure SS1 and the second stack structure SS2 may be arranged at different vertical levels. Although the first stack structure SS1 and the second stack structure SS2 are separated in FIG. 3 for convenience of understanding, the memory device 120 may have a structure in which a bottom surface of the second stack structure SS2 is attached to a top surface of the first stack structure SS1.

The first stack structure SS1 includes a region where the MCA 121 of FIG. 2 is arranged, and bit lines, word lines, and memory cells may be arranged. The second stack structure SS2 includes a first core region CR1 and a second core region CR2 where the core circuits of the first to fourth banks BANK1 to BANK4 of FIG. 2 are arranged and may further include a peripheral circuit region. The first core region CR1 and the second core region CR2 may be arranged at a position vertically overlapping the memory cell region MCR, and may include core circuits electrically connected to the memory cell region MCR. In some embodiments, the first core region CR1 may include first to fourth sense amplifiers 2082a, 2082b, 2082c, and 2082d, and the first to fourth sense amplifiers 2082a, 2082b, 2082c, and 2082d may be electrically connected to the bit lines included in the first stack structure SS1. In some embodiments, the second core region CR2 may include first to fourth processing elements 2085a, 2085b, 2085c, and 2085d, and the first to fourth processing elements 2085a, 2085b, 2085c, and 2085d may be electrically connected to first to fourth sense amplifiers 2082a, 2082b, 2082c, and 2082d. The peripheral circuit region may include peripheral circuits of the memory device 120 (e.g., an address buffer 210, a control logic circuit 126, an input/output gating circuit 2090, and a data input/output buffer 2095).

Referring to FIG. 4, the bank BANK1 may include a plurality of sub-cell blocks SCB. The plurality of sub-cell blocks SCB may be arranged spaced apart in a second horizontal direction (Y). A sub-cell block SCB may include a plurality of bit lines BL, a plurality of word lines WL, and a plurality of memory cells MC. Each of the plurality of memory cells MC may include one cell transistor TR and one cell capacitor CAP connected to the one cell transistor TR. Each of the plurality of memory cells MC may have a 1 transistor-1 capacitor 1T1C structure.

The plurality of word lines WL may extend in the second horizontal direction (Y) and may be arranged to be spaced apart from each other in the first horizontal direction (X) and the vertical direction (Z). The plurality of bit lines BL may extend in the vertical direction (Z) and may be arranged to be spaced apart from each other in the first horizontal direction (X) and the second horizontal direction (Y). One cell transistor TR may be arranged between one word line WL and one bit line BL.

A gate of the cell transistor TR may be connected to the word line WL, and a source of the cell transistor TR may be connected to the bit line BL via a first contact DC. The cell transistor TR may be connected to the cell capacitor CAP through a second contact BC. A drain of the cell transistor TR may be connected to a first electrode of the cell capacitor CAP through the second contact BC, and a second electrode of the cell capacitor CAP may be connected to a plate electrode PP.

Within one sub-cell block SCB, the plurality of cell transistors TR may be arranged at positions that overlap each other in the vertical direction (Z). Within one sub-cell block SCB, the plurality of cell capacitors CAP may be arranged at positions that overlap each other in the vertical direction (Z). One cell transistor TR and one cell capacitor CAP may be arranged side by side at the same vertical level, and a memory cell MC composed of one cell transistor TR and one cell capacitor CAP may be stacked in multiple numbers in the vertical direction (Z). The storage capacity of a sub-cell block SCB can vary depending on the number or layers of memory cells MC stacked in the vertical direction (Z) (e.g., the number or layers of cell capacitors CAPs.

Referring to FIGS. 5 and 6, the memory device 120 may include the first stack structure SS1 and the second stack structure SS2, and the second stack structure SS2 may be bonded to the first stack structure SS1 by first and second bonding pads BP1 and BP2.

The first stack structure SS1 may include a memory cell region MCR. The first stack structure SS1 may include a plurality of first semiconductor patterns 520, a plurality of bit lines BL, a plurality of word lines WL, and a cell capacitor CAP arranged on a first substrate 510 in the memory cell region MCR. In the memory cell region MCR, the plurality of first semiconductor patterns 520 may be arranged on the first substrate 510 extending in a first horizontal direction (X) and spaced apart in the vertical direction (Z). The plurality of first semiconductor patterns 520 may include an undoped semiconductor material or a doped semiconductor material and may have a line shape or a bar shape extending in the first horizontal direction (X). In some embodiments, each of the first semiconductor patterns 520 may include a channel region 520A, and a first impurity region 520S and a second impurity region 520D arranged in the first horizontal direction (X) with the channel region 520A therebetween. The first impurity region 520S may be connected to the bit line BL, and the second impurity region 520D may be connected to the cell capacitor CAP. An ohmic metal layer including a metal silicide, etc. may further be formed between the first impurity region 520S and the bit line BL, and between the second impurity region 520D and the cell capacitor CAP.

The plurality of word lines WL may be arranged on upper and lower surfaces of the plurality of first semiconductor patterns 520 and may extend in the second horizontal direction (Y) and be spaced apart in the vertical direction (Z). One word line WL among the plurality of word lines WL may surround the plurality of first semiconductor patterns 520 spaced apart from each other in the second horizontal direction (Y) and may extend in the second horizontal direction (Y). Two word lines WL spaced apart from each other in the vertical direction (Z) among the plurality of word lines WL may be arranged at positions where the two word lines WL overlap each other in the vertical direction (Z). A gate insulating layer 530 may be disposed between the word line WL and the first semiconductor pattern 520. The gate insulating layer 530 may include at least one material selected from a high-k dielectric material and a ferroelectric material having a higher dielectric constant than silicon oxide. The plurality of bit lines BL may extend in the vertical direction (Z) on the first substrate 510 and may be spaced apart from each other in the second horizontal direction (Y). The plurality of bit lines BL may be any one of a doped semiconductor material, a conductive metal nitride, a metal, and a metal-semiconductor compound.

The cell capacitor CAP may include a first electrode EL1, a capacitor dielectric layer DL, and a second electrode EL2. The first electrode EL1 may be arranged to extend in a first horizontal direction (X) and be spaced apart in the vertical direction (Z). The first electrode EL1 may have an internal space (not shown) extending in the first horizontal direction (X), and the internal space may be filled with the capacitor dielectric layer DL and the second electrode EL2. For example, the first electrode EL1 may have a cup shape rotated 90 degrees. The capacitor dielectric layer DL may include at least one material selected from a high-k dielectric material and a ferroelectric material having a dielectric constant greater than silicon oxide. The second electrode EL2 may fill the internal space of the first electrode EL1, and the capacitor dielectric layer DL may be disposed between the internal space of the first electrode EL1 and the second electrode EL2. The first electrode EL1 and the second electrode EL2 may include a doped semiconductor material, a conductive metal nitride, or a conductive metal oxide. A plate electrode PP may be arranged on one side of the cell capacitor CAP to extend in a vertical direction (Z) and a second horizontal direction (Y). The second electrode EL2 of the cell capacitor CAP may be electrically connected to the plate electrode PP, for example, may be commonly connected to the plurality of second electrodes EL2 arranged to be spaced apart in the vertical direction (Z) and the plurality of second electrodes EL2 arranged to be spaced apart in the second horizontal direction (Y).

Insulating material layers 522 may be arranged between two adjacent first semiconductor patterns 520 spaced apart in the vertical direction (Z), between two adjacent word lines WL spaced apart in the vertical direction (Z), between two adjacent first electrodes EL1 spaced apart in the vertical direction (Z), and between two bit lines BL spaced apart in the second horizontal direction (Y).

An upper wiring structure 650 may be arranged on the memory cell region MCR. The upper wiring structure 650 may include a wiring layer 652, a via 654, and an insulating layer 656. The upper wiring structure 650 may further include a contact 658 electrically connected to the bit line BL, the word line WL, and the plate electrode PP. In addition, a first bonding pad BP1 arranged on the same plane as the uppermost surface of the insulating layer 656 may be formed on the upper wiring structure 650.

The second stack structure SS2 may include a second substrate 610, a peripheral circuit transistor 620 disposed on the second substrate 610, a front wiring structure 630 covering the peripheral circuit transistor 620 on an upper surface of the second substrate 610, and a rear wiring structure 640 disposed on a bottom surface of the second substrate 610. The front wiring structure 630 may include a wiring layer 632, a via 634, and an insulating layer 636, and the rear wiring structure 640 may include a wiring layer 642, a via 644, and an insulating layer 646.

The rear wiring structure 640 may include a second bonding pad BP2 arranged on the same plane as a bottom surface of the insulating layer 646, and as the second bonding pad BP2 and the first bonding pad BP1 are connected to each other, the first stack structure SS1 and the second stack structure SS2 may be bonded. An interface between the insulating layer 656 of the upper wiring structure 650 and the insulating layer 646 of the rear wiring structure 640 may be flatly extended and may be arranged on the same plane as an interface between the first bonding pad BP1 and the second bonding pad BP2.

In some embodiments, the peripheral circuit transistor 620 may include a gate electrode 622 and a gate insulating layer 624 disposed on an active region of the second substrate 610. In some embodiments, the peripheral circuit transistor 620 disposed on the first core region CR1 may be included in a sense amplifier (e.g., the first sense amplifier 2082a), and the sense amplifier may be electrically connected to bit lines BL included in the first stack structure SS1.

In some embodiments, the second stack structure SS2 may further include a through via 660 penetrating the second substrate 610, and the wiring layer 632 included in the front wiring structure 630 may be electrically connected to the wiring layer 642 included in the rear wiring structure 640 by the through via 660, and the wiring layer 642 included in the rear wiring structure 640 may be electrically connected to the bit line BL of the upper wiring structure 650 through the second bonding pad BP2 and the first bonding pad BP1.

FIGS. 7 to 9 are diagrams illustrating processing elements within a memory device according to some embodiments.

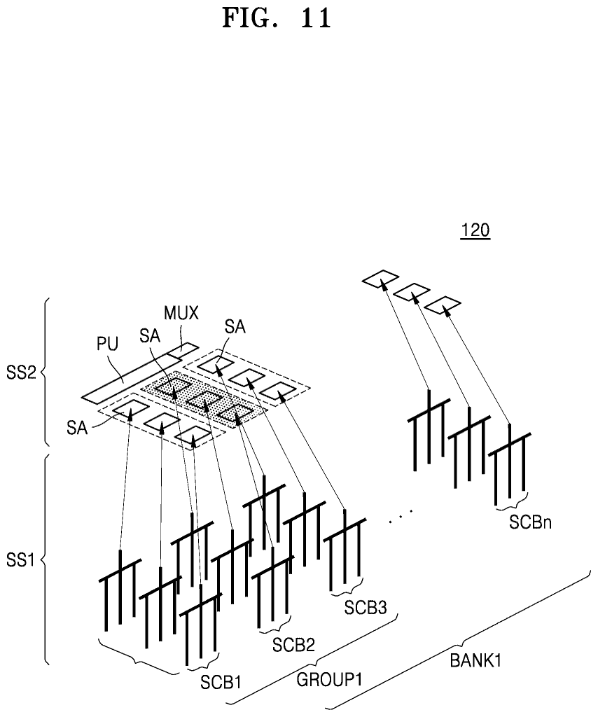

Referring to FIG. 7, the first bank BANK1 includes a first bank array 2080a, and the first bank array 2080a may include a plurality of sub-cell blocks SCB. In the present embodiment, the first bank array 2080a is described as being composed of two sub-cell blocks SCB1 and SCB2, but is not limited thereto and may include a variety of sub-cell blocks (e.g., SCBn in FIG. 11, where n is a natural number). In the first bank array 2080a, one of the plurality of sub-cell blocks SCBn may be activated, and the activated sub-cell block refers to a sub-cell block including memory cells selected by an activated word line among the word lines WL of the first bank BANK1.

The first bank array 2080a may include a first sub-cell block SCB1 and a second sub-cell block SCB2. Data read from the first sub-cell block SCB1 or the second sub-cell block SCB2 may be loaded into the first sense amplifier 2082a via the bit line BL. Data loaded into the first sense amplifier 2082a may be data of the bit lines BL connected to the memory cells selected from the first sub-cell block SCB1 or the second sub-cell block SCB2. The data loaded into the first sense amplifier 2082a may be provided to the first processing element 2085a. Hereinafter, for convenience of explanation, the first sense amplifier 2082a may be used interchangeably as a sense amplifier SA, and the first processing element 2085a may be used as a processing element PE.

The processing element PE may include a first switch circuit SW1, a second switch circuit SW2, a multiplexer circuit MUX, and a processing unit PU. Data loaded into the sense amplifier SA connected to the first sub-cell block SCB1 may be transmitted to the processing unit PU through the first switch circuit SW1 or to a local input/output line LIO. Data loaded into the sense amplifier SA connected to the second sub-cell block SCB2 may be transferred to the processing unit PU through the second switch circuit SW2 or to the local input/output line LIO.

The processing unit PU may perform bit vector operations associated with GEMM, GEMV, or data compression. A bit vector may refer to a number of physically contiguous bits, whether physically contiguous in rows (e.g., horizontally oriented) or physically contiguous in columns (e.g., vertically oriented). The bit vector operations may include logical operations, such as Boolean operations (e.g., AND, OR, XOR, etc.), and transfer operations, such as shifting data values and inverting data values, for example, in a sub-cell block SCB of a first bank array 2080a. Arithmetic operations performed by a processing unit PU may be enabled by logical operations.

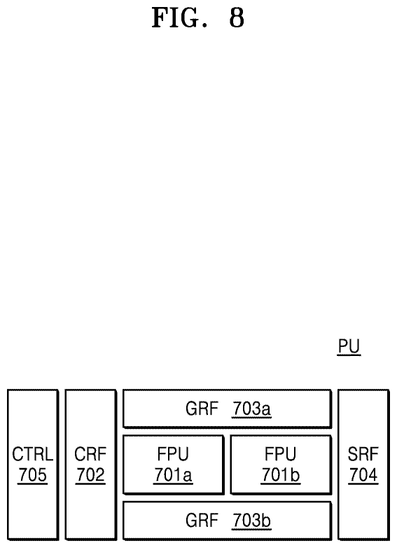

In some embodiments, the processing unit PU may include floating-point units FPU 701a and 701b, a first register file 702, second register files 703a and 703b, a third register file 704, and a controller 705 as illustrated in FIG. 8. For example, the processing unit PU may include a multiply-accumulate unit. The floating-point units FPU 701a and 701b may be a computational component including multipliers and adders. The register files may include the first register file 702 used as an instruction and/or address buffer, the second register files 703a and 703b storing data loaded from a sub-cell block SCB of the first bank array 2080a, and the third register file 704 used for each of the multiplications and additions. The controller 705 may be responsible for controlling the flow of instructions stored in the first register file 702 and fetching and decoding instructions to sequence accesses to the sub-cell block SCB of the first bank array 2080a. The controller 705 may include timing circuits and timing management circuits and may be responsible for executing instructions by controlling the generation of clock signals and the application of clock signals to the computational components in relation to performing bit vector operations.

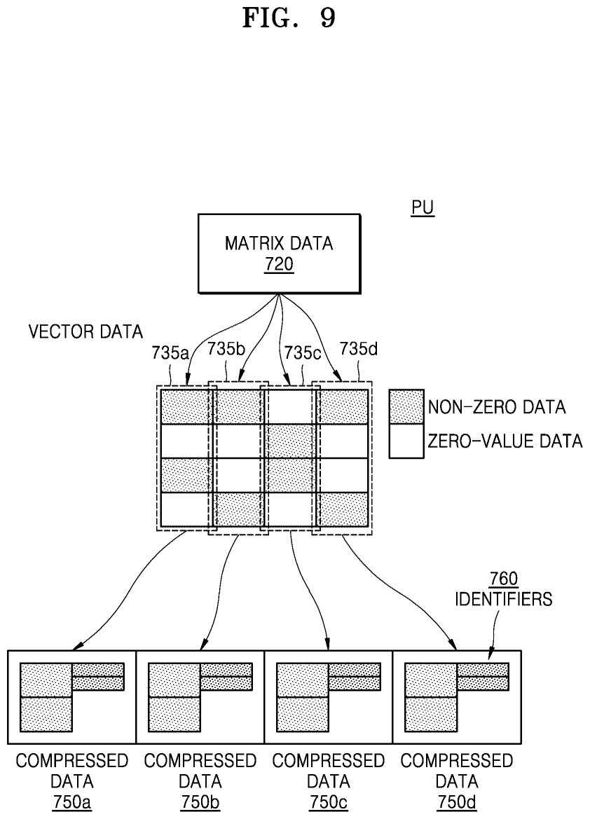

In some embodiments, matrix data 720 operated on in the processing unit PU of FIG. 9 may include non-zero elements depicted in the shaded area and zero elements depicted in the white area. For example, each of vector data 735a-d may include four elements. The first and third elements of the vector data 735a are non-zero, and the second and fourth elements of the vector data 735a are zero. The first and fourth elements of the vector data 735b are non-zero, and the second and third elements of the vector data 735b are zero. The second and third elements of the vector data 735c are non-zero, and the first and fourth elements of the vector data 735c are zero. The first and fourth elements of the vector data 735d are non-zero, and the second and third elements of the vector data 735d are zero. The processing unit PU may process each piece of vector data 735a-d to generate each piece of compressed data 750a-d, where each piece of compressed data may include only non-zero elements having identifiers 760 indicating relative locations to the original vector data 735a-d. The identifiers 760 may be generated based on an index mapping or a bitmap.

The multiplexer circuit MUX of FIG. 7 may generate a first processing mode signal PMS1 or a second processing mode signal PMS2 based on a processing mode signal PMS provided from the control logic circuit 126. The first processing mode signal PMS1 may be configured to be activated in response to the processing mode signal PMS when the first sub-cell block SCB1 is activated, and the second processing mode signal PMS2 may be configured to be activated in response to the processing mode signal PMS when the second sub-cell block SCB2 is activated.

The first switch circuit SW1 may include a first transistor PT1 connected between the sense amplifier SA connected to the first sub-cell block SCB1 and the processing unit PU, and a second transistor MT1 connected between the sense amplifier SA and the local input/output line LIO. The first transistor PT1 may transfer data of the first sub-cell block SCB1 loaded into the sense amplifier SA to the processing unit PU in response to activation of the first processing mode signal PMS1. The second transistor MT1 may transfer data of the first sub-cell block SCB1 loaded into the sense amplifier SA to the local input/output line LIO in response to activation of the memory mode signal MMS.

When the memory device 120 is in a memory mode, data of the first sub-cell block SCB1 sensed by the sense amplifier SA is selectively transferred to the local input/output line LIO by the column select transistors, and the local input/output line sense amplifier may amplify data of the local input/output line LIO. Data of the local input/output line LIO amplified by a local input/output line sense amplifier may be output as read data through a global data path GDP and a data input/output buffer 2095 to a memory controller 114 (see FIG. 1) outside the memory device 120 through the data DQ pad(s). The global data path GDP may include a global input/output line and a global input/output line sense amplifier that amplifies data of the global input/output line.

When the memory device 120 is in an internal processing mode, data of the first sub-cell block SCB1 sensed by the sense amplifier SA is transmitted to the processing unit PU, and the result data processed by the processing unit PU may be output as read data through the global data path GDP and the data input/output buffer 2095 to the memory controller 114 (see FIG. 1) outside the memory device 120 through the data DQ pad(s).

The second switch circuit SW2 may include a first transistor PT2 connected between the sense amplifier SA and the processing unit PU and a second transistor MT2 connected between the sense amplifier SA and the local input/output line LIO. The first transistor PT2 may transmit data of the second sub-cell block SCB2 loaded into the sense amplifier SA to the processing unit PU in response to activation of the second processing mode signal PMS2. The second transistor MT2 may transmit data of the second sub-cell block SCB2 loaded into the sense amplifier SA to the local input/output line LIO in response to activation of the memory mode signal MMS.

When the memory device 120 is in the memory mode, data of the second sub-cell block SCB2 sensed by the sense amplifier SA is transmitted to the local input/output line LIO, and the local input/output line sense amplifier may amplify data of the local input/output line LIO. Data of the local input/output line LIO amplified by a local input/output line sense amplifier may be output as read data through a global data path GDP and a data input/output buffer 2095 to the memory controller 114 (see FIG. 1) outside the memory device 120 through data DQ pad(s).

When the memory device 120 is in the internal processing mode, data of the second sub-cell block SCB2 sensed by the sense amplifier SA is transmitted to the processing unit PU, and the result data processed by the processing unit PU may be output as read data through the global data path GDP and the data input/output buffer 2095 to the memory controller 114 (see FIG. 1) outside the memory device 120 through the data DQ pad(s).

In FIG. 7, the processing unit PU is shared between two sub-cell blocks SCB1 and SCB2 through a multiplexer circuit MUX, thereby reducing the chip size of the memory device 120. Alternatively, a processing unit PU may exist for each of the sub-cell blocks SCB1 and SCB2, but this may potentially cause a problem of increasing the chip size of the memory device.

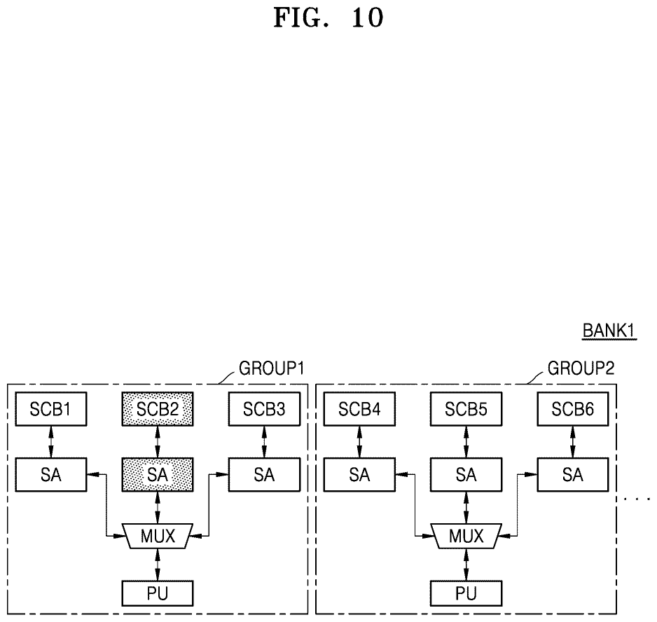

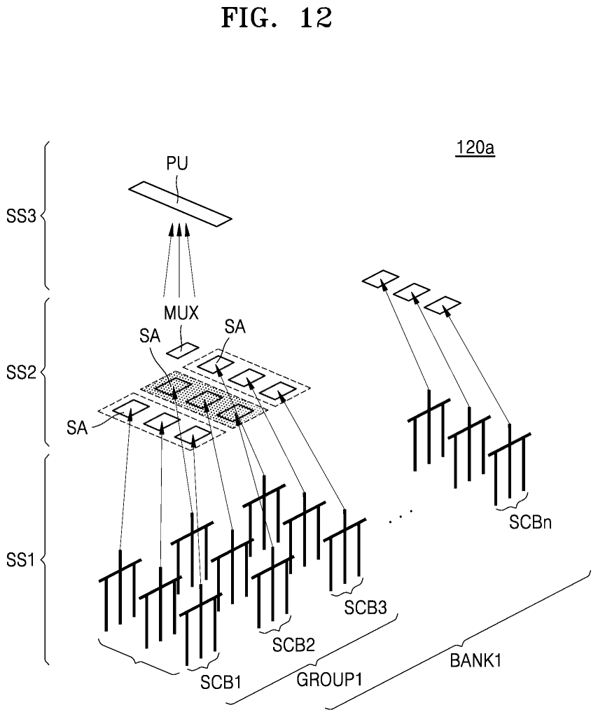

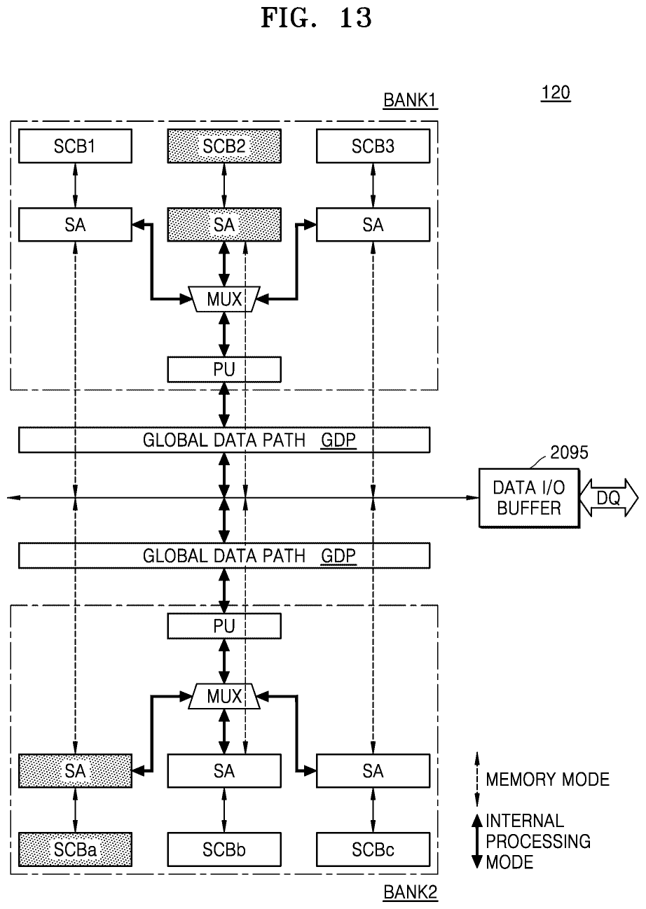

FIGS. 10 to 13 are diagrams illustrating banks within a memory device according to embodiments. FIGS. 10 and 13 are diagrams for explaining the circuit architecture of the bank, and FIGS. 11 and 12 are diagrams for explaining a semiconductor structure of the bank.

Referring to FIG. 10, the bank BANK1 shows a configuration in which three sub-cell blocks SCB1-3 and SCB4-6 are grouped among a plurality of sub-cell blocks SCBs and share a processing unit PU. The first to third sub-cell blocks SCB1, SCB2, and SCB3 of the first group may be connected to a multiplexer circuit MUX through a corresponding sense amplifier SA. The fourth to sixth sub-cell blocks SCB4, SCB5, and SCB6 of the second group may be connected to a multiplexer circuit MUX through a corresponding sense amplifier SA. The bank BANK1 may have one of a number of sub-cell blocks SCBn, for example, the second sub-cell block SCB2, activated. When the memory device 120 is in the internal processing mode, the sense amplifier SA connected to the second sub-cell block SCB2 of the first group may be connected to the processing unit PU by a multiplexer circuit MUX.

Referring to FIGS. 5, 6, 10, and 11, bit lines BL (sometimes called local bit lines) of a plurality of sub-cell blocks SCBn of the bank BANK1 are arranged in the first stack structure SS1 of the memory device 120, and a predetermined number of bit lines BL may be grouped and connected to a global bit line GBL. Because the global bit line GBL is electrically connected to the bit line BL and functions in the same way as the bit line BL, the global bit line GBL may be referred to as a bit line BL.

The sense amplifier SA corresponding to each of the grouped sub-cell blocks SCB1-3 and SCB4-6 may be arranged in the second stack structure SS2. Also, a multiplexer circuit MUX and a processing unit PU connected to a sense amplifier SA corresponding to the first to third sub-cell blocks SCB1, SCB2, and SCB3 of the first group may be arranged in the second stack structure SS2. In addition, a multiplexer circuit MUX and a processing unit PU connected to a sense amplifier SA corresponding to the fourth to sixth sub-cell blocks SCB4, SCB5, and SCB6 of the second group may be arranged in the second stack structure SS2.

Referring to FIG. 12, the memory device 120a differs from the memory device 120 in FIG. 11 in that the sense amplifier SA corresponding to the first to third sub-cell blocks SCB1, SCB2, and SCB3 of the first group and the multiplexer circuit MUX connected to the sense amplifier SA are arranged in the second stack structure SS2, but the processing unit PU is arranged in a third stack structure SS3. The third stack structure SS3 may have a structure that is vertically stacked on the second stack structure SS2, and a structure in which a bottom surface of the third stack structure SS3 is attached to an upper surface of the second stack structure SS2.

The processing throughput and performance associated with the processing unit PU may be expanded. For example, a hardware component having an improved hardware architecture may be generated in the processing unit PU according to a combination of a structure, size, bit rate, etc. of input data to be processed and various processing requirements. In this case, an area occupied by the processing element 2085 including the processing unit PU may increase. The second core region CR2 of FIG. 3 may cause a problem in that the chip size of the memory device 120 increases due to the area occupied by the processing element 2085. The memory device 120a may be manufactured so that the processing unit PU is arranged on the third stack structure SS3 stacked on the second stack structure SS2 in order to reduce the chip size.

Referring to FIG. 13, the memory device 120 may include a first bank BANK1 and a second bank BANK2 including a plurality of sub-cell blocks SCBs. The first bank BANK1 and the second bank BANK2 may share a processing unit PU through a multiplexer circuit MUX by grouping at least two or more sub-cell blocks. In the present embodiments, the first bank BANK1 may be connected to the processing unit PU through a multiplexer circuit MUX in which three sub-cell blocks SCB1, SCB2, and SCB3 are connected to the sub-cell blocks SCB1, SCB2, and SCB3. The second bank BANK2 may be connected to the processing unit PU through a multiplexer circuit MUX in which three sub-cell blocks SCBa, SCBb, and SCBc are connected to the sub-cell blocks SCBa, SCBb, and SCBc.

When the memory device 120 is in a memory mode, one of the activated sub-cell blocks SCB1, SCB2, and SCB3 of the first bank BANK1 is electrically connected to a corresponding sense amplifier SA, and data of the sub-cell blocks sensed by the sense amplifier SA may be output to the memory controller 114 (see FIG. 1) outside the memory device 120 through a local input/output line LIO (see FIG. 7), the global data path GDP, and the data input/output buffer 2095 through data DQ pad(s). Among the sub-cell blocks SCBa, SCBb, and SCBc of the second bank BANK2, one activated sub-cell block is electrically connected to a corresponding sense amplifier SA, and data of the sub-cell block sensed by the sense amplifier SA may be output to the memory controller 114 outside the memory device 120 through the data DQ pad(s) via the local input/output line LIO, the global data path GDP, and the data input/output buffer 2095.

When the memory device 120 is in the internal processing mode, one sub-cell block (e.g., SCB2) that is activated among the sub-cell blocks SCB1, SCB2, and SCB3 of the first bank BANK1 is electrically connected to a corresponding sense amplifier SA, data of the sub-cell block SCB2 sensed by the sense amplifier SA is connected to a processing unit PU through a multiplexer circuit MUX, and result data processed by the processing unit PU may be output to the memory controller 114 outside the memory device 120 through data DQ pad(s) via the global data path GDP and the data input/output buffer 2095. Among the sub-cell blocks SCBa, SCBb, and SCBc of the second bank BANK2, one activated sub-cell block (e.g., SCBa) is electrically connected to a corresponding sense amplifier SA, data of the SCBa sub-cell block sensed by the sense amplifier SA is connected to a processing unit PU through a multiplexer circuit MUX, and the result data processed by the processing unit PU may be output to the memory controller 114 outside the memory device 120 through data DQ pad(s) via the global data path GDP and a data input/output buffer 2095.

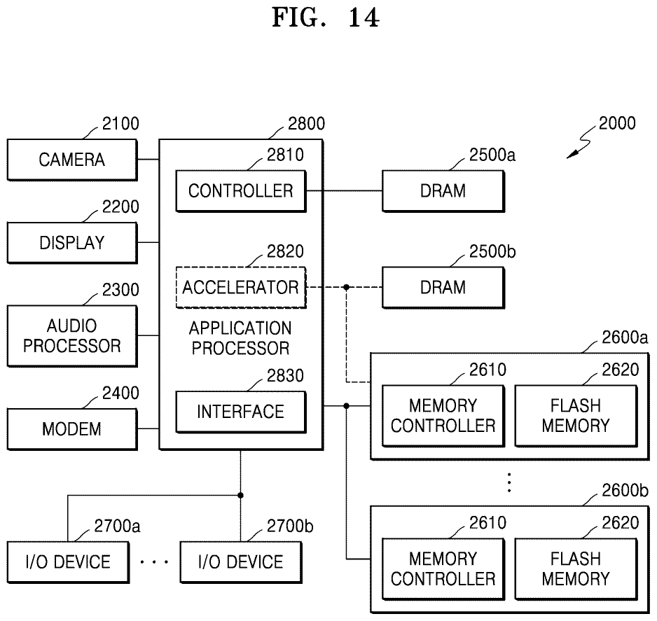

FIG. 14 is a block diagram of a system 2000 for explaining an electronic device including a memory device according to embodiments.

Referring to FIG. 14, the system 2000 may include a camera 2100, a display 2200, an audio processor 2300, a modem 2400, DRAMs 2500a and 2500b, flash memories 2600a and 2600b, I/O devices 2700a and 2700b, and an application processor 2800 (hereinafter referred to as “AP”). The system 2000 may be implemented as a laptop computer, a mobile phone, a smartphone, a tablet personal computer, a wearable device, a healthcare device, or an Internet of Things (IoT) device. In addition, the system 2000 may be implemented as a server or a personal computer.

The camera 2100 may capture still images or videos under the user's control and store the captured image/video data or transmit still images or videos to the display 2200. The audio processor 2300 may process audio data included in the flash memories 2600a and 2600b or content of a network. The modem 2400 may modulate and transmit a signal for wired/wireless data transmission and reception, and demodulate the signal to restore the signal to the original signal at the receiving end. The I/O devices 2700a and 2700b may include devices that provide digital input and/or output functions, such as a universal serial bus (USB), storage, a digital camera, a secure digital (SD) card, a digital versatile disc (DVD), a network adapter, a touch screen, etc.

The AP 2800 may control the overall operation of the system 2000. The AP 2800 may include a control block 2810, an accelerator block or an accelerator chip 2820, and an interface block 2830. The AP 2800 may control the display 2200 so that a portion of the content stored in the flash memories 2600a and 2600b is displayed on the display 2200. When a user input is received through the I/O devices 2700a and 2700b, the AP 2800 may perform a control operation corresponding to the user input. The AP 2800 may include an accelerator block, which is a dedicated circuit for artificial intelligence (AI) data operation, or may have an accelerator chip 2820 separately from the AP 2800. The DRAM 2500b may be additionally mounted on the accelerator block or the accelerator chip 2820. The accelerator is a functional block that specializes in performing a specific function of the AP 2800, and the accelerator may include a GPU, which is a functional block that specializes in performing graphic data processing, an NPU, which is a block that specializes in performing AI calculations and inference, and a data processing unit (DPU), which is a block that specializes in data transmission.

The system 2000 may include a plurality of DRAMs 2500a and 2500b. The AP 2800 may control the DRAMs 2500a and 2500b through commands and mode register MRS settings that conform to the Joint Electron Device Engineering Council (JEDEC) standard specifications, or may communicate by setting a DRAM interface protocol to use the company's unique functions such as low voltage/high speed/reliability and cyclic redundancy check (CRC)/error correction code (ECC) functions. For example, the AP 2800 may communicate with the DRAM 2500a through an interface conforming to JEDEC standard specifications such as LPDDR4 and LPDDR5, and the accelerator block or the accelerator chip 2820 may communicate by setting a new DRAM interface specification to control the DRAM 2500b for an accelerator having a higher bandwidth than the DRAM 2500a.

In FIG. 14, only the DRAMs 2500a and 2500b are illustrated, but embodiments are not limited thereto, and any memory, such as PRAM, SRAM, MRAM, RRAM, FRAM, or Hybrid RAM, may be used as long as it satisfies the bandwidth, response speed, and voltage conditions of the AP 2800 or the accelerator chip 2820. The DRAMs 2500a and 2500b have relatively smaller latency and bandwidth than the I/O devices 2700a and 2700b or the flash memories 2600 and 2600b. The DRAMs 2500a and 2500b are initialized at the power-on time of the system 2000, and an operating system and application data are loaded, and may be used as temporary storage for the operating system and application data, or as an execution space for various software code.

Within the DRAMs 2500a and 2500b, arithmetic operations such as addition/subtraction/multiplication/division, vector operations, address operations, or Fast Fourier Transform (FFT) operations may be performed. In addition, a function for performing inference may be performed within the DRAMs 2500a and 2500b. Here, inference may be performed in a deep learning algorithm using an artificial neural network. The deep learning algorithm may include a training step for learning a model through various data and an inference step for recognizing data with the learned model. As an example, an image captured by a user through the camera 2100 is signal-processed and stored within the DRAM 2500b, and the accelerator block or accelerator chip 2820 may perform an AI data operation for recognizing data using the data stored in the DRAM 2500b and a function used for inference.

The system 2000 may include a plurality of storages or a plurality of flash memories 2600a and 2600b having a larger capacity than the DRAMs 2500a and 2500b. The accelerator block or accelerator chip 2820 may perform a training operation and AI data calculation using the flash memories 2600a and 2600b. In embodiments, the flash memories 2600a and 2600b include a memory controller 2610 and a flash memory device 2620 and may more efficiently perform the training operation and inference AI data calculation performed by the AP 2800 and/or the accelerator chip 2820 using a calculation device provided in the memory controller 2610. The flash memories 2600a and 2600b may store photos taken by the camera 2100 or store data transmitted through a data network. For example, the flash memories 2600a and 2600b may store Augmented Reality/Virtual Reality, High Definition (HD), or Ultra High Definition (UHD) content.

The DRAMs 2500a and 2500b of the system 2000 may include memory devices described with reference to FIGS. 1 to 13. The memory devices may include a first stack structure in which at least two sub-cell blocks are included in a first sub-cell block group and a second sub-cell block group in a bank including a plurality of cell transistors and a plurality of cell capacitors arranged in three dimensions. A second stack structure disposed on the first stack structure may include first sense amplifiers connected to sub-cell blocks belonging to the first sub-cell block group and second sense amplifiers connected to sub-cell blocks belonging to the second sub-cell block group. In addition, the second stack structure may include a multiplexer circuit and a processing unit that are shared by each of the first sub-cell block group and the second sub-cell block group. Alternatively, the processing unit may be included in the second stack structure disposed on the second stack structure. Through such a memory device, data of an activated sub-cell block may be efficiently fed to a processing element including a processing unit that performs matrix-matrix multiplication, matrix-vector multiplication, and/or bit vector operations associated with data compression while reducing the area overhead of the memory device. These memory devices may be usefully applied when the processing throughput and performance associated with the processing unit are expanded.

As described above, example embodiments of the inventive concept have been disclosed in the drawings and specification. In the present specification, the example embodiments are described by using some specific terms, but the terms used are for the purpose of describing the technical scope of the inventive concept only and are not intended to be limiting of meanings or the technical scope described in the claims. Therefore, it will be understood by those skilled in the art that various changes in form and details may be made therein without departing from the spirit and scope of the inventive concept as defined by the appended claims. Accordingly, the scope of the invention is defined not by the detailed description of the invention but by the appended claims.

While the inventive concept has been particularly shown and described with reference to embodiments thereof, it will be understood that various changes in form and details may be made therein without departing from the spirit and scope of the following claims.

What is claimed is:

1. A memory device comprising: a first stack structure comprising:
a memory cell array region including a bank divided into a plurality of sub-cell blocks, wherein the plurality of sub-cell blocks are included in a first sub-cell block group and a second sub-cell block group, and each of the first sub-cell block group and the second sub-cell block group includes at least two or more sub-cell blocks; and
a second stack structure disposed on the first stack structure, comprising:
a sense amplifier region including sense amplifiers connected to memory cells through a plurality of bit lines of the plurality of sub-cell blocks, wherein the sense amplifiers include first sense amplifiers connected to sub-cell blocks belonging to the first sub-cell block group and second sense amplifiers connected to sub-cell blocks belonging to the second sub-cell block group;
a multiplexer circuit region including a multiplexer circuit corresponding to each of the first sub-cell block group and the second sub-cell block group; and
a processing element region including a processing element corresponding to each of the first sub-cell block group and the second sub-cell block group, wherein the processing element includes a processing unit that performs a logical operation on data transmitted by the multiplexer circuit as an operand.

2. The memory device of claim 1, wherein the multiplexer circuit corresponding to the first sub-cell block group connects the processing element and the sense amplifiers connected to the first sub-cell block that is activated in the first sub-cell block group among the first sense amplifiers when the memory device is in an internal processing mode.

3. The memory device of claim 2, wherein:
the second stack structure further includes a first switch circuit connected between the first sense amplifiers and the processing element, and
data of the first sub-cell block is transmitted to the processing unit through the first switch circuit.

4. The memory device of claim 1, wherein the multiplexer circuit corresponding to the second sub-cell block group connects the processing element and the sense amplifiers connected to the second sub-cell block activated in the second sub-cell block group among the second sense amplifiers when the memory device is in an internal processing mode.

5. The memory device of claim 4, wherein:
the second stack structure further includes a second switch circuit connected between the second sense amplifiers and the processing element, and
data of the second sub-cell block is transmitted to the processing unit through the second switch circuit.

6. The memory device of claim 1, wherein the first stack structure includes the memory cell array region including a plurality of cell transistors and a plurality of cell capacitors arranged three-dimensionally.

7. The memory device of claim 6, wherein the memory device comprises:
a first substrate;
a first semiconductor pattern disposed on the first substrate in the memory cell array region and extending in a first direction substantially parallel to an upper surface of the first substrate;
a word line surrounding the first semiconductor pattern and extending in a second direction substantially parallel to the upper surface of the first substrate; and
a bit line connected to a first end of the first semiconductor pattern and extending in a third direction substantially perpendicular to the upper surface of the first substrate.

8. The memory device of claim 7, wherein:
the cell capacitor is connected to a second end opposite to the first end of the first semiconductor pattern; and
the cell capacitor extends in the first direction.

9. A memory device comprising:
a first stack structure comprising:
a memory cell array region including a bank divided into a plurality of sub-cell blocks, wherein the plurality of sub-cell blocks are included in a first sub-cell block group and a second sub-cell block group, and each of the first sub-cell block group and the second sub-cell block group includes at least two or more sub-cell blocks;
a second stack structure disposed on the first stack structure, comprising:
a sense amplifier region including sense amplifiers connected to memory cells through a plurality of bit lines of the plurality of sub-cell blocks, wherein the sense amplifiers include first sense amplifiers connected to sub-cell blocks belonging to the first sub-cell block group and second sense amplifiers connected to sub-cell blocks belonging to the second sub-cell block group; and
a multiplexer circuit region including a multiplexer circuit corresponding to each of the first sub-cell block group and the second sub-cell block group; and
a third stack structure disposed on the second stack structure, comprising:
a processing element region including processing elements corresponding to each of the first sub-cell block group and the second sub-cell block group, wherein the processing elements include a processing unit that performs a logical operation on data transmitted by the multiplexer circuit as an operand.

10. The memory device of claim 9, wherein the multiplexer circuit corresponding to the first sub-cell block group connects the processing element and the sense amplifiers connected to the first sub-cell block that is activated in the first sub-cell block group among the first sense amplifiers when the memory device is in an internal processing mode.

11. The memory device of claim 10, wherein:
the second stack structure further includes a first switch circuit connected between the first sense amplifiers and the processing element, and
data of the first sub-cell block is transmitted to the processing unit through the first switch circuit.

12. The memory device of claim 9, wherein the multiplexer circuit corresponding to the second sub-cell block group connects the processing element and the sense amplifiers connected to the second sub-cell block that is activated in the second sub-cell block group among the second sense amplifiers when the memory device is in an internal processing mode.

13. The memory device of claim 12, wherein:
the second stack structure further includes a second switch circuit connected between the second sense amplifiers and the processing element, and
data of the second sub-cell block is transmitted to the processing unit through the second switch circuit.

14. The memory device of claim 9, wherein the first stack structure includes a memory cell array region including a plurality of cell transistors and a plurality of cell capacitors arranged three-dimensionally.

15. The memory device of claim 14, wherein:
the memory device comprises: a first substrate;
a first semiconductor pattern disposed on the first substrate in the memory cell array region and extending in a first direction substantially parallel to an upper surface of the first substrate;
a word line surrounding the first semiconductor pattern and extending in a second direction substantially parallel to the upper surface of the first substrate; and
a bit line connected to a first end of the first semiconductor pattern and extending in a third direction substantially perpendicular to the upper surface of the first substrate.

16. The memory device of claim 15, wherein:
the cell capacitor is connected to a second end opposite to the first end of the first semiconductor pattern; and
the cell capacitor extends in the first direction.

17. A memory device comprising:
a memory cell array including a bank divided into a plurality of sub-cell blocks, wherein the plurality of sub-cell blocks are included in a first sub-cell block group and a second sub-cell block group, and each of the first sub-cell block group and the second sub-cell block group includes at least two or more sub-cell blocks;
sense amplifiers connected to memory cells through a plurality of bit lines of the plurality of sub-cell blocks, wherein the sense amplifiers include first sense amplifiers connected to sub-cell blocks belonging to the first sub-cell block group and second sense amplifiers connected to sub-cell blocks belonging to the second sub-cell block group;
a multiplexer circuit corresponding to each of the first sub-cell block group and the second sub-cell block group;
a processing element corresponding to each of the first sub-cell block group and the second sub-cell block group, wherein the processing element includes a processing unit that performs a logical operation on data transmitted by the multiplexer circuit as an operand;
a first switch circuit connecting the first sense amplifiers and the processing element by the multiplexer circuit; and
a second switch circuit connecting the second sense amplifiers and the processing element by the multiplexer circuit.

18. The memory device of claim 17, wherein the memory cell array includes a plurality of cell transistors and a plurality of cell capacitors arranged three-dimensionally.

19. The memory device of claim 18, wherein:
the memory device includes a first stack structure and a second stack structure disposed on the first stack structure, and
the memory cell array is included in the first stack structure, and the sense amplifiers, the processing element, the first switch circuit, and the second switch circuit are included in the second stack structure.

20. The memory device of claim 17, wherein:
the memory device includes a first stack structure, a second stack structure disposed on the first stack structure, and a third stack structure disposed on the second stack structure, and
the memory cell array is included in the first stack structure, the sense amplifiers, the first switch circuit, and the second switch circuit are included in the second stack structure, and the processing element is included in the third stack structure.
